(19) United States
(12) Patent Application Publication
(10) Pub. No.: US 2025/0299749 A1
(43) Pub. Date: Sep. 25, 2025

(54) SEMICONDUCTOR INTEGRATED CIRCUIT, MEMORY CONTROLLER, AND CONTROL METHOD OF SEMICONDUCTOR INTEGRATED CIRCUIT

(71) Applicant: Kioxia Corporation, Tokyo (JP)

(72) Inventor: Atsuki KOBAYASHI, Fujisawa Kanagawa (JP)

(21) Appl. No.: 19/063,147

(22) Filed: Feb. 25, 2025

(30) Foreign Application Priority Data
Mar. 22, 2024 (JP) 2024-046387
Jun. 18, 2024 (JP) 2024-098281

(51) Int. Cl. G11C 16/30

(52) U.S. Cl. CPC G11C 16/30

(57) ABSTRACT

A semiconductor integrated circuit includes a plurality of step-down circuits, a plurality of input switches, and a plurality of output switches. The plurality of step-down circuits are configured to step down a first voltage that is input and to output a first stepped-down voltage or to step down a second voltage that is input and to output a second stepped-down voltage. The plurality of input switches are connected to input terminals of the plurality of step-down circuits, respectively, and each of the input switches is configured to switch an input to the corresponding input terminal to either the first voltage or the second voltage. The plurality of output switches are connected to output terminals of the plurality of step-down circuits, respectively, and each of the output switches is configured to switch an output from the corresponding output terminal to either a first output node or a second output node.

### CROSS-REFERENCE TO RELATED APPLICATION(S)

This application is based upon and claims the benefit of priority from Japanese Patent Application No. 2024-046387, filed Mar. 22, 2024, and Japanese Patent Application No. 2024-098281, filed Jun. 18, 2024, the entire contents of both of which are incorporated herein by reference.

### FIELD

Embodiments described herein relate generally to a semiconductor integrated circuit, a memory controller, and a control method of a semiconductor integrated circuit.

### BACKGROUND

In the related art, in a circuit that corrects temperature characteristics of a circuit element using a diode voltage difference, a voltage step-down circuit is used for conversion into a voltage suitable for an input voltage range of a circuit to which the diode voltage difference is input. In general, in order to implement a high-accuracy temperature characteristic correction function, for a stepped-down voltage that is output from the voltage step-down circuit, changes caused by a variation in a circuit element need to be small.

### BRIEF DESCRIPTION OF THE DRAWINGS

FIG. 1 is a block diagram illustrating an example of a configuration of a memory system.

FIG. 2 is a circuit diagram illustrating a configuration of a voltage step-down circuit according to a first comparative example.

FIG. 3 is a circuit diagram illustrating a configuration of a voltage step-down circuit according to a second comparative example.

FIG. 4 is a timing chart illustrating control waveforms of switches of the voltage step-down circuit according to the second comparative example.

FIG. 5 is a circuit diagram illustrating a configuration of a voltage step-down circuit according to an embodiment.

FIG. 6 is a timing chart illustrating control waveforms of switches of the voltage step-down circuit according to the embodiment.

FIG. 7 is a circuit diagram illustrating a configuration of a current generator circuit.

### DETAILED DESCRIPTION

Embodiments provide a semiconductor integrated circuit capable of obtaining a stepped-down voltage that is only slightly affected by a variation in a circuit element, a memory controller, and a control method of a semiconductor integrated circuit.

In general, according to one embodiment, a semiconductor integrated circuit includes a plurality of step-down circuits, a plurality of input switches, and a plurality of output switches. The plurality of step-down circuits are configured to step down a first voltage that is input and to output a first stepped-down voltage or to step down a second voltage that is input and to output a second stepped-down voltage. The plurality of input switches are connected to input terminals of the plurality of step-down circuits, respectively, and each of the input switches is configured to switch an input to the corresponding input terminal to either the first voltage or the second voltage. The plurality of output switches are connected to output terminals of the plurality of step-down circuits, respectively, and each of the output switches is configured to switch an output from the corresponding output terminal to either a first output node or a second output node.

Hereinafter, an embodiment will be described in detail with reference to the drawings.

### First Embodiment

### Configuration of Memory System

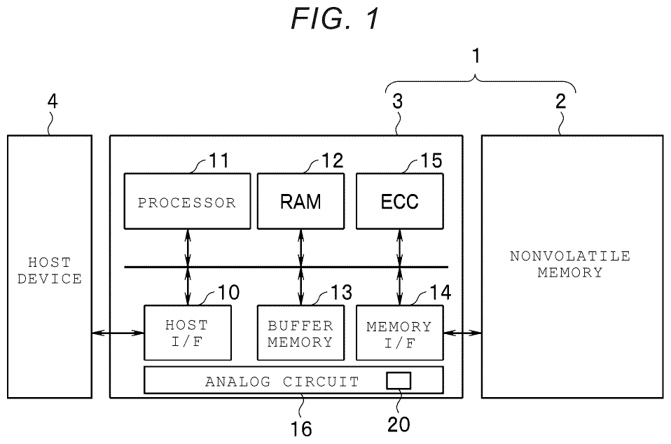

FIG. 1 is a block diagram illustrating an example of a configuration of a memory system. A memory system 1 according to the present embodiment includes a memory controller 3 and a nonvolatile memory 2. The nonvolatile memory 2 may include a plurality of memory chips. The memory system 1 can be connected to a host device 4. The host device 4 is, for example, an electronic apparatus such as a personal computer or a mobile terminal.

The memory system 1 may have a configuration in which a plurality of chips of the memory system 1 are mounted on a motherboard on which the host device 4 is mounted, or may be configured as a system large-scale integrated circuit (LSI) or a system-on-a-chip (SoC) where the memory system 1 is implemented as one module. Examples of the memory system 1 include a memory card such as a SD card, a solid-state-drive (SSD), and an embedded-multi-media-card (eMMC).

The nonvolatile memory 2 is a NAND memory including a plurality of memory cells and stores data in a nonvolatile manner.

The memory controller 3 issues commands to write (also referred to as “program”), read, or erase data into or from the nonvolatile memory 2, for example, in response to a command from the host device 4. In addition, the memory controller 3 manages a memory space of the nonvolatile memory 2. The memory controller 3 includes a host interface (host I/F) circuit 10, a processor 11, a random access memory (RAM) 12, a buffer memory 13, a memory interface circuit (memory I/F) circuit 14, an error checking and correcting (ECC) circuit 15, and an analog circuit 16. The nonvolatile memory 2 is an example of “semiconductor memory device”.

The host I/F circuit 10 is connected to the host device 4 via a host bus and executes interface processing with the host device 4. In addition, the host I/F circuit 10 transmits and receives a command, an address, and data to and from the host device 4.

The processor 11 is configured with, for example, a central processing unit (CPU). The processor 11 controls an overall operation of the memory controller 3. For example, when a write command is received from the host device 4, the processor 11 issues a write command corresponding to the write command from the host device 4 to the nonvolatile memory 2 via the memory I/F circuit 14. The read command and the erase command operate in a similar manner. In addition, the processor 11 executes various processes such as wear leveling for managing the nonvolatile memory 2. The processor 11 is an example of “control circuit”.

The RAM 12 is used as a work area of the processor 11 and stores, for example, firmware data loaded from the nonvolatile memory 2 or various tables generated by the processor 11. The RAM 12 is configured with, for example, a DRAM or a SRAM.

The buffer memory 13 temporarily stores data transmitted from the host device 4, and temporarily stores data transmitted from the nonvolatile memory 2.

The memory I/F circuit 14 is connected to the nonvolatile memory 2 via a bus, and executes interface processing with the nonvolatile memory 2. In addition, the memory I/F circuit 14 transmits and receives a command, an address, and data to and from the nonvolatile memory 2.

When data is written, the ECC circuit 15 generates an error-correcting code for the write data, adds the error-correcting code to the write data, and transmits the data to the memory I/F circuit 14. In addition, when the data is read, the ECC circuit 15 executes error detection and/or error correction on the read data using the error-correcting code in the read data. The ECC circuit 15 may be provided in the memory I/F circuit 14.

The analog circuit 16 is provided to support an operation of the memory system. The analog circuit 16 includes an oscillator circuit or a reference voltage circuit. The oscillator circuit or the reference voltage circuit includes a voltage step-down circuit 20 of the semiconductor integrated circuit according to the present embodiment. Before describing a configuration of the voltage step-down circuit 20 according to the present embodiment, voltage step-down circuits according to comparative examples will be described.

Voltage Step-Down Circuit according to Comparative Example 1

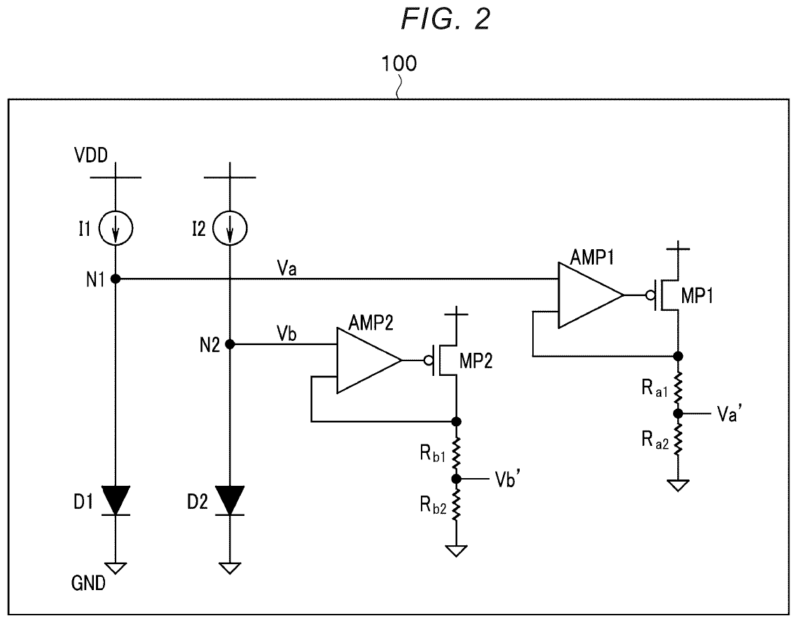

FIG. 2 is a circuit diagram illustrating a configuration of a voltage step-down circuit according to Comparative Example 1.

A voltage step-down circuit 100 according to Comparative Example 1 includes constant current sources I1 and I2, diodes D1 and D2, operational amplifiers AMP1 and AMP2, PMOS transistors MP1 and MP2, and resistors Rₐ₁, Rₐ₂, R_{b1}, and R_{b2}.

The constant current source I1 and the diode D1 are connected in series between a power supply voltage VDD and a ground GND. Likewise, the constant current source I2 and the diode D2 are connected in series between the power supply voltage VDD and the ground GND.

One terminal of the operational amplifier AMP1 is connected to a node N1 between the constant current source I1 and the diode D1, and another terminal thereof is connected to a drain of the PMOS transistor MP1. An output terminal of the operational amplifier AMP1 is connected to a gate terminal of the PMOS transistor MP1. A voltage Va applied to the diode D1 is input to one terminal of the operational amplifier AMP1.

In the PMOS transistor MP1, a gate is connected to the output terminal of the operational amplifier AMP1, a source is connected to the power supply voltage VDD, and a drain is connected to the other terminal of the operational amplifier AMP1 and the resistor Rₐ₁.

A feedback loop is formed by the operational amplifier AMP1 and the PMOS transistor MP1, and the voltage Va is applied to a series resistor configured with the resistors Rₐ₁ and Rₐ₂. A voltage Va′ that is stepped down (divided) by the resistors Rₐ₁ and Rₐ₂ is output from a node between the resistors Rₐ₁ and Rₐ₂.

One terminal of the operational amplifier AMP2 is connected to a node N2 between the constant current source I2 and the diode D2, and another terminal thereof is connected to a drain of the PMOS transistor MP2. An output terminal of the operational amplifier AMP2 is connected to a gate terminal of the PMOS transistor MP2. A voltage Vb applied to the diode D2 is input to one terminal of the operational amplifier AMP2.

In the PMOS transistor MP2, a gate is connected to the output terminal of the operational amplifier AMP2, a source is connected to the power supply voltage VDD, and a drain is connected to the other terminal of the operational amplifier AMP2 and the resistor R_{b1}.

A feedback loop is formed by the operational amplifier AMP2 and the PMOS transistor MP2, and the voltage Vb is applied to a series resistor configured with the resistors R_{b1} and R_{b2}. A voltage Vb′ that is stepped down (divided) by the resistors R_{b1} and R_{b2} is output from a node between the resistors R_{b1} and R_{b2}.

Assuming that a current value output from the constant current source I1 is N times a current value output from the constant current source I2 and an area of the diode D2 is M times an area of the diode D1, a difference between the voltage Va applied to the diode D1 and the voltage Vb applied to the diode D2 is represented by Expression (1).

$$Va - Vb = \frac{k T}{q} ln ( MN ) \qquad ( 1 )$$

Here, k represents a Boltzmann constant, T represents a temperature, and q represents an elementary charge.

Since the operational amplifier AMP1 and the PMOS transistor MP1 form the feedback loop, the voltage applied to the series resistor configured with the resistors Rₐ₁ and Rₐ₂ is the voltage Va.

Likewise, since the operational amplifier AMP2 and the PMOS transistor MP2 form the feedback loop, the voltage applied to the series resistor configured with the resistors R_{b1} and R_{b2} is the voltage Vb.

Therefore, the voltage Va′ divided by the resistor Rₐ₁ and Rₐ₂ and the voltage Vb′ divided by the resistor R_{b1} and R_{b2} are represented by Expression (2) and Expression (3), respectively.

$${Va}^{′} = \frac{{R}_{a 2}}{{R}_{a 1} + {R}_{a 2}} Va \qquad ( 2 )$$

$${Vb}^{′} = \frac{{R}_{b 2}}{{R}_{b 1} + {R}_{b 2}} Vb \qquad ( 3 )$$

Here, assuming that all the resistance values of the resistors Rₐ₁, Rₐ₂, R_{b1}, and R_{b2}are the same (alternatively, the resistance values of the resistors Rₐ₁ and R_{b1} are the same and the resistance values of the resistors Rₐ₂ and R_{b2} are the same) and a step-down ratio is DR, the step-down ratio DR and the diode voltage difference Va′-Vb′ are represented by Expression (4) and Expression (5), respectively.

$${D}_{R} = \frac{{R}_{a 2}}{{R}_{a 1} + {R}_{a 2}} = \frac{{R}_{b 2}}{{R}_{b 1} + {R}_{b 2}} \qquad ( 4 )$$

$${Va}^{′} - {Vb}^{′} = {D}_{R} \frac{k T}{q} ln ( MN ) \qquad ( 5 )$$

As a result, the diode voltage difference Va′-Vb′ that changes in proportion to the temperature can be obtained, and temperature characteristics of another circuit element can be corrected using this diode voltage difference Va′-Vb′.

In addition, by changing the resistance values of the resistors Rₐ₁, Rₐ₂, R_{b1}, and R_{b2}, the step-down ratio DR can be changed depending on an input voltage range of a circuit to which the diode voltage difference Va′-Vb′ is input.

However, due to the effect of a variation of a circuit element in a semiconductor integrated circuit, a step-down ratio when the voltage Va is stepped down to Va′ and a step-down ratio when the voltage Vb is stepped down to Vb′ do not completely match with each other in the voltage step-down circuit 100, and the diode voltage difference Va′-Vb′ varies. Voltage Step-Down Circuit according to Comparative Example 2

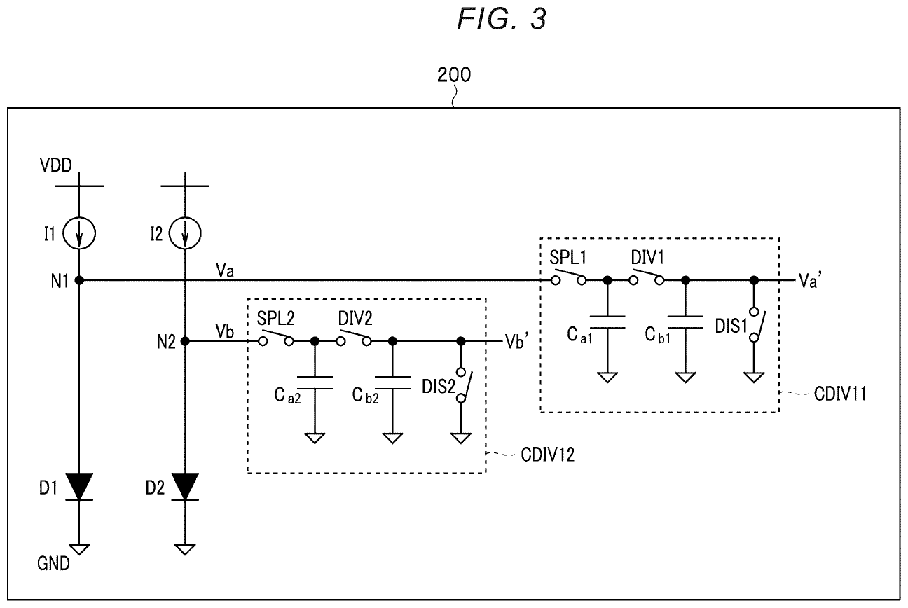

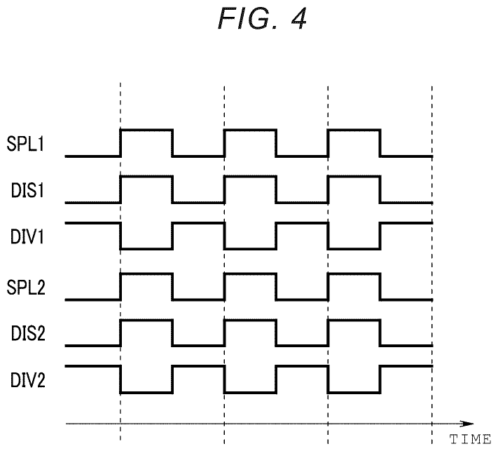

FIG. 3 is a circuit diagram illustrating a configuration of a voltage step-down circuit according to Comparative Example 2. FIG. 4 is a timing chart illustrating control waveforms of switches of the voltage step-down circuit according to Comparative Example 2. Each of the switches in the timing chart illustrated in FIG. 4 is ON when the control waveform is at a high level (High), and is OFF when the control waveform is at a low level (Low). In FIG. 3, the same components as those of FIG. 2 are represented by the same reference numerals, and the description thereof will not be repeated.

A voltage step-down circuit 200 according to Comparative Example 2 includes constant current sources I1 and I2, diodes D1 and D2, and capacitive step-down circuits CDIV11 and CDIV12. The capacitive step-down circuit CDIV11 includes switches SPL1, DIV1, and DIS1 and capacitors Cₐ₁ and C_{b1}. The capacitive step-down circuit CDIV12 includes switches SPL2, DIV2, and DIS2 and capacitors Cₐ₂ and C_{b2}.

The switches SPL1 and DIV1 are connected in series to a node N1. The capacitors Cₐ₁ and C_{b1} and the switch DIS1 are connected in parallel to the node N1. In the capacitor Cₐ₁, one end is connected to a node between the switches SPL1 and DIV1, and another end is connected to a ground GND. In the capacitor C_{b1}, one end is connected to the switch DIV1, and another end is connected to the ground GND.

When the switches SPL1 and DIS1 are switched on and the switch DIV1 is switched off, the capacitor Cₐ₁ is charged with the voltage Va, and charge in the capacitor C_{b1} is discharged. When the switches SPL1 and DIS1 are switched off and the switch DIV1 is switched on, the voltage Va′ that is stepped down when the capacitor Cₐ₁ charged with the voltage Va is connected to the capacitor C_{b1}, is output.

The switches SPL2 and DIV2 are connected in series to a node N2. The capacitors Cₐ₂ and C_{b2} and the switch DIS2 are connected in parallel. In the capacitor Cₐ₂, one end is connected to a node between the switches SPL2 and DIV2, and another end is connected to the ground GND. In the capacitor C_{b2}, one end is connected to the switch DIV2, and another end is connected to the ground GND.

When the switches SPL2 and DIS2 are switched on and the switch DIV2 is switched off, the charge Cₐ₂ is charged with the voltage Vb, and charge in the capacitor C_{b2} is discharged. When the switches SPL2 and DIS2 are switched off and the switch DIV2 is switched on, the voltage Vb′ that is stepped down when the capacitor Cₐ₂ charged with the voltage Vb is connected to the capacitor C_{b2}, is output.

As illustrated in FIG. 4, the switch SPL1 is switched on/off in synchronization with the switch DIS1. The switch DIV1 is switched off in a period where the switch SPL1 is switched on, and is switched on in a period where the switch SPL1 is switched off.

Likewise, the switch SPL2 is switched on/off in synchronization with the switch DIS2. The switch DIV2 is switched off in a period where the switch SPL2 is switched on, and is switched on in a period where the switch SPL2 is switched off.

By operating the switches SPL1, DIV1, and DIS1, as in the waveforms illustrated in FIG. 4, the charging and discharging of the capacitors Cₐ₁ and C_{b1} are repeated. In addition, by operating the switches SPL2, DIV2, and DIS2, as in the waveforms illustrated in FIG. 4, the charging and discharging of the capacitors Cₐ₂ and C_{b2} are repeated. As a result, the voltage Va′ and the voltage Vb′ are represented by Expression (6) and Expression (7), respectively.

$${Va}^{′} = \frac{{C}_{a 1}}{{C}_{a 1} + {C}_{b 1}} Va \qquad ( 6 )$$

$${Vb}^{′} = \frac{{C}_{a 2}}{{C}_{a 2} + {C}_{b 2}} Vb \qquad ( 7 )$$

Here, assuming that all the capacitance values of the capacitors Cₐ₁, C_{b1}, Cₐ₂, and C_{b2} are the same (alternatively, the capacitance values of the capacitors Cₐ₁ and Cₐ₂ are the same and the capacitance values of the capacitors C_{b1} and C_{b2} are the same) and a step-down ratio is D_{C}, the step-down ratio D_{C} and the diode voltage difference Va′-Vb′ are represented by Expression (8) and Expression (9), respectively.

$${D}_{C} = \frac{{C}_{a 1}}{{C}_{a 1} + {C}_{b 1}} = \frac{{C}_{a 2}}{{C}_{a 2} + {C}_{b 2}} \qquad ( 8 )$$

$${Va}^{′} - {Vb}^{′} = {D}_{c} \frac{kT}{q} ln ( MN ) \qquad ( 9 )$$

This way, in the voltage step-down circuit 200 according to Comparative Example 2, as in the voltage step-down circuit 100 according to Comparative Example 1, the diode voltage difference Va′-Vb′ that changes in proportion to the temperature can be obtained.

In the voltage step-down circuit 200, the number of circuit elements is smaller than that of the voltage step-down circuit 100, and thus the effect of a variation of a circuit element is small.

However, even in the voltage step-down circuit 200, the effect of a variation of a circuit element caused by the switches SPL1, SPL2, DIV1, DIV2, DIS1, and DIS2 and the capacitors Cₐ₁, C_{b1}, Cₐ₂, and C_{b2} remains. Therefore, in the voltage step-down circuit 200, as in the voltage step-down circuit 100 according to Comparative Example 1, a step-down ratio when the voltage Va is stepped down to Va′ and a step-down ratio when the voltage Vb is stepped down to Vb′ do not completely match with each other, and the diode voltage difference Va′-Vb′ varies.

In addition, even in a period where the switch SPL1 is switched off, the voltage Va′ that is an output voltage varies due to a leakage current flowing from the constant current source I1 to the capacitor Cₐ₁. Likewise, even in a period where the switch SPL2 is switched off, the voltage Vb′ that is an output voltage varies due to a leakage current flowing from the constant current source I2 to the capacitor Cₐ₂.

### Voltage Step-Down Circuit of Present Embodiment

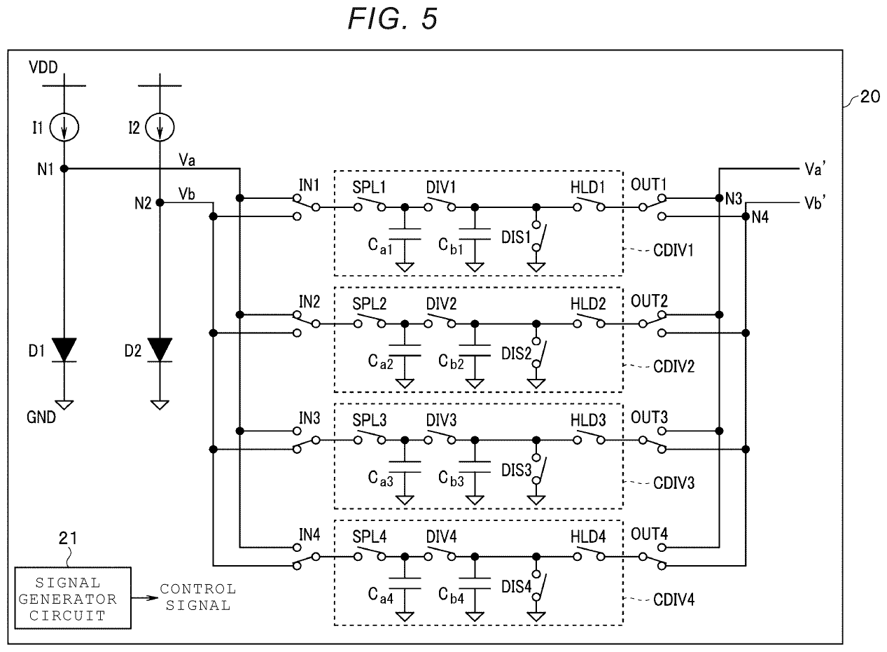

FIG. 5 is a circuit diagram illustrating a configuration of the voltage step-down circuit according to the present embodiment. In FIG. 5, the same components as those of FIG. 3 are represented by the same reference numerals, and the description thereof will not be repeated.

The voltage step-down circuit 20 includes a signal generator circuit 21, constant current sources I1 and I2, diodes D1 and D2, capacitive step-down circuits CDIV1, CDIV2, CDIV3, and CDIV4, switches IN1, IN2, IN3, and IN4, and switches OUT1, OUT2, OUT3, and OUT4. The voltage step-down circuit 20 is an example of “semiconductor integrated circuit”. The capacitive step-down circuits CDIV1, CDIV2, CDIV3, and CDIV4 are examples of “the plurality of step-down circuits (the first step-down circuit, the second step-down circuit, the third step-down circuit, and the fourth step-down circuit). The switches IN1, IN2, IN3, and IN4 are examples of “the plurality of input switches (the first input switch, the second input switch, the third input switch, and the fourth input switch)”. The switches OUT1, OUT2, OUT3, and OUT4 are examples of “the plurality of output switches (the first output switch, the second output switch, the third output switch, and the fourth output switch)”. The constant current sources I1 and I2 are examples of “the first constant current source” and “the second constant current source”. The diodes D1 and D2 are examples of “the first diode” and “the second diode”.

The capacitive step-down circuit CDIV1 is configured by adding a switch HLD1 to the capacitive step-down circuit CDIV11 of FIG. 3. One end of the switch HLD1 is connected to a switch DIV1, and another end thereof is connected to the switch OUT1.

A switch SPL1 is a switch for controlling whether to charge a capacitor Cₐ₁ with the voltage Va applied to the diode D1 or the voltage Vb applied to the diode D2. The switch DIV1 is a switch for connecting the capacitor Cₐ₁ to a capacitor C_{b1} to execute a step-down operation. The switch DIS1 is a switch for discharging the capacitor C_{b1}. The switch HLD1 is a switch to cut-off an output when the capacitor C_{b1} is discharged or the step-down operation is executed. The switch OUT1 is a switch for controlling whether to output the stepped-down voltage Va′ or Vb′ to a node N3 or N4. The voltage Va or the voltage Vb is an example of “the first voltage” or “the second voltage”. The voltage Va′ or the voltage Vb′ is an example of “the first stepped-down voltage” or “the second stepped-down voltage”.

The capacitive step-down circuit CDIV2 is configured by adding a switch HLD2 to the capacitive step-down circuit CDIV12 of FIG. 3. One end of the switch HLD2 is connected to a switch DIV2, and another end thereof is connected to the switch OUT2. The switch HLD2 is a switch to cut-off an output when the capacitor C_{b2} is discharged or the step-down operation is executed. The switch OUT2 controls whether to output the stepped-down voltage Va′ or Vb′.

In addition, configurations of the capacitive step-down circuit CDIV3 and CDIV4 are the same as that of the capacitive step-down circuit CDIV1. The capacitive step-down circuit CDIV3 includes switches SPL3, DIV3, DIS3, and HLD3 and capacitors Cₐ₃ and C_{b3}. In addition, the capacitive step-down circuit CDIV4 includes switches SPL4, DIV4, DIS4, and HLD4 and capacitors Cₐ₄ and C_{b4}. As in the capacitive step-down circuits CDIV1 and CDIV2, the capacitive step-down circuits CDIV3 and CDIV4 correspond to the capacitive step-down circuits CDIV11 and CDIV12 of FIG. 3, respectively.

The switches SPL1, SPL2, SPL3, and SPL4 are examples of “the first switch”. The capacitors Cₐ₁, Cₐ₂, Cₐ₃, and Cₐ₄ are examples of “the first capacitor”. The capacitors C_{b1}, C_{b2}, C_{b3}, and C_{b4} are examples of “the second capacitor”. The switches DIV1, DIV2, DIV3, and DIV4 are examples of “the second switch”. The switches DIS1, DIS2, DIS3, and DIS4 are examples of “the third switch”. The switches HLD1, HLD2, HLD3, and HLD4 are examples of “the fourth switch”.

The switches IN1, IN2, IN3, and IN4 switch whether to connect inputs (input terminals) of the capacitive step-down circuits CDIV1, CDIV2, CDIV3, and CDIV4 to the node N1 or the node N2, respectively. Due to the switching control of the switches IN1, IN2, IN3, and IN4, the voltage Va applied to the diode D1 or the voltage Vb applied to the diode D2 is input to the capacitive step-down circuits CDIV1, CDIV2, CDIV3, and CDIV4.

The switches OUT1, OUT2, OUT3, and OUT4 switch whether to output outputs (output terminals) of the capacitive step-down circuits CDIV1, CDIV2, CDIV3, and CDIV4 to the node N3 or the node N4, respectively. Due to the switching control of the switches OUT1, OUT2, OUT3, and OUT4, the capacitive step-down circuits CDIV1, CDIV2, CDIV3, and CDIV4 output the stepped-down voltage Va′ to the node N3 or output the stepped-down voltage Vb′ to the node N4.

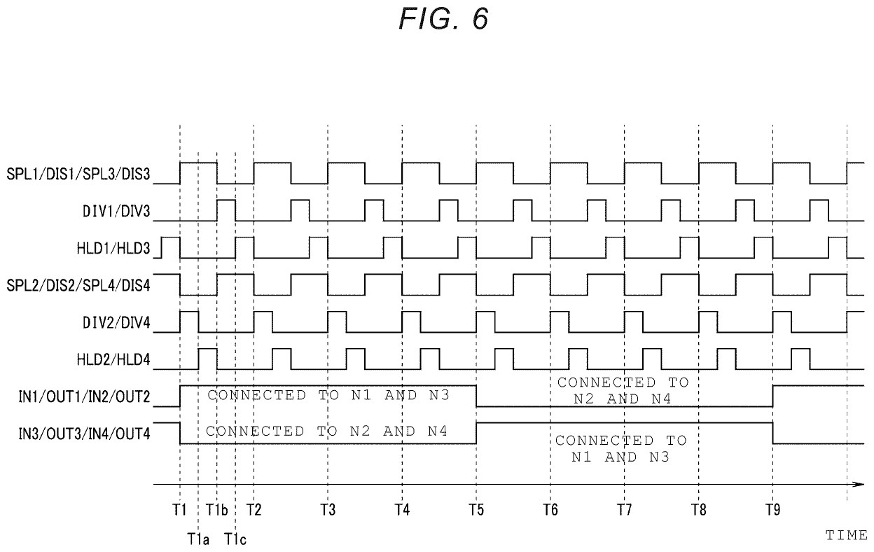

The signal generator circuit 21 outputs a control signal for controlling each of the switches in the voltage step-down circuit 20. Specifically, the signal generator circuit 21 generates each of control signals illustrated in FIG. 6 to be supplied to the switches IN1 to IN4, OUT1 to OUT4, SPL1 to SPL4, DIV1 to DIV4, DIS1 to DIS4, and HLD1 to HLD4. For example, the signal generator circuit 21 may be configured with dedicated hardware such as an analog circuit, or may be configured with a processor using a CPU, an FPGA, or the like. In addition, the signal generator circuit 21 may be configured to operate to generate the control signal according to a program stored in a memory (not illustrated), or may implement some or all of the functions in the analog circuit of the hardware.

FIG. 6 is a timing chart illustrating control waveforms of the switches of the voltage step-down circuit according to the present embodiment.

As illustrated in FIG. 6, the switches SPL1, DIS1, SPL3, and DIS3 are switched on/off in synchronization with each other. Likewise, the switches DIV1 and DIV3 are switched on/off in synchronization with each other. Likewise, the switches HLD1 and HLD3 are switched on/off in synchronization with each other.

In addition, the switches SPL2, DIS2, SPL4, and DIS4 are switched on/off in synchronization with each other. Likewise, the switches DIV2 and DIV4 are switched on/off in synchronization with each other. Likewise, the switches HLD2 and HLD4 are switched on/off in synchronization with each other.

When the switch SPL1 is switched on (high level), the switch SPL2 operates to be switched off (low level), and when the switch SPL1 is switched off (low level), the switch SPL2 operates to be switched on (high level). The switches DIS1 and DIS2 have the same relationship and so do the switches SPL3 and SPL4, and the switches DIS3 and DIS4.

When the switches SPL1, DIS1, SPL3, and DIS3 are switched off, the switches DIV1 and DIV3 operate to be switched on. When the switches DIV1 and DIV3 are switched off, the switches HLD1 and HLD3 operate to be switched on.

When the switches SPL2, DIS2, SPL4, and DIS4 are switched off, the switches DIV2 and DIV4 operate to be switched on. When the switches DIV2 and DIV4 are switched off, the switches HLD2 and HLD4 operate to be switched on.

The switches IN1 and OUT1 for selecting connection targets of the input and output of the capacitive step-down circuit CDIV1 and the switches IN2 and OUT2 for selecting connection targets of the input and output of the capacitive step-down circuit CDIV2 are switched on/off in synchronization with each other.

The control signals to be supplied to the switches IN1, OUT1, IN2, and OUT2 are signals that are divided from a signal of the switch SPL1. As described above, these control signals are generated by the signal generator circuit 21. In the example of FIG. 6, the control signals are four signals that are divided from the signal of the switch SPL1. The division ratio at which the signal of the switch SPL1 is divided is not limited to 4 and may be 2 or more. In addition, the control signals to be supplied to the switches IN1, OUT1, IN2, and OUT2 may be signals that are divided from signals of the switches DIS1, SPL3, and DIS3.

In a period T1 to T5 where the control signals to be supplied to the switches IN1, OUT1, IN2, and OUT2 are at a high level, the inputs of the capacitive step-down circuits CDIV1 and CDIV2 are connected to the voltage Va, and the outputs are connected to the voltage Va′.

On the other hand, in a period T5 to T9 where the control signals to be supplied to the switches IN1, OUT1, IN2, and OUT2 are at a low level, the inputs of the capacitive step-down circuits CDIV1 and CDIV2 are connected to the voltage Vb, and the outputs are connected to the voltage Vb′.

The switches IN3 and OUT3 for selecting connection targets of the input and output of the capacitive step-down circuit CDIV3 and the switches IN4 and OUT4 for selecting connection targets of the input and output of the capacitive step-down circuit CDIV4 are switched on/off in synchronization with each other.

The control signals to be supplied to the switches IN3, OUT3, IN4, and OUT4 are logically opposite to the control signals to be supplied to the switches IN1, OUT1, IN2, and OUT2. That is, the control signals to be supplied to the switches IN3, OUT3, IN4, and OUT4 are at a low level in a period where the control signals to be supplied to the switches IN1, OUT1, IN2, and OUT2 are at a high level, and are at a high level in a period where the control signals to be supplied to the switches IN1, OUT1, IN2, and OUT2 are at a low level.

In the period T1 to T5 where the control signals to be supplied to the switches IN3, OUT3, IN4, and OUT4 are at a low level, the inputs of the capacitive step-down circuits CDIV3 and CDIV4 are connected to the voltage Vb, and the outputs are connected to the voltage Vb′.

On the other hand, in the period T5 to T9 where the control signals to be supplied to the switches IN3, OUT3, IN4, and OUT4 are at a high level, the inputs of the capacitive step-down circuits CDIV3 and CDIV4 are connected to the voltage Va, and the outputs are connected to the voltage Va′.

This way, the voltage step-down circuit 20 uses the capacitive step-down circuits CDIV1 and CDIV2 as one set and uses the capacitive step-down circuits CDIV3 and CDIV4 as another set to step down the voltage Va applied to the diode D1 (alternatively, the voltage Vb applied to the diode D2).

Specifically, in a period T1 to T1b, the switches SPL1 and DIS1 of the capacitive step-down circuit CDIV1 are switched on. In the period T1 to T1b, the capacitive step-down circuit CDIV1 charges the capacitor Cₐ₁ with the voltage Va applied to the diode D1, and discharges the capacitor C_{b1}.

Meanwhile, in a period T1 to T1a, by switching on the switch DIV2 of the capacitive step-down circuit CDIV2, the capacitor Cₐ₂ charged with the voltage Va is connected to the capacitor C_{b2} to execute the step-down operation. Next, in a period T1a to T1b, by switching on the switch HLD2, the capacitive step-down circuit CDIV2 outputs the voltage Va′ that is stepped down from the voltage Va.

On the other hand, in a period T1b to T2, the switches SPL2 and DIS2 of the capacitive step-down circuit CDIV2 are switched on. In the period T1b to T2, the capacitive step-down circuit CDIV2 charges the capacitor Cₐ₂ with the voltage Va applied to the diode D1, and discharges the capacitor C_{b2}.

Meanwhile, in a period T1b to T1c, by switching on the switch DIV1 of the capacitive step-down circuit CDIV1, the capacitor Cₐ₁ charged with the voltage Va is connected to the capacitor C_{b1} to execute the step-down operation. Next, in a period T1c to T2, by switching on the switch HLD1, the capacitive step-down circuit CDIV1 outputs the voltage Va′ that is stepped down from the voltage Va.

That is, by alternately operating the capacitive step-down circuits CDIV1 and CDIV2 as one set, the capacitor Cₐ₁ of the capacitive step-down circuit CDIV1 and the capacitor Cₐ₂ of the capacitive step-down circuit CDIV2 are always charged with the voltage Va applied to the diode D1 (alternatively, the voltage Vb applied to the diode D2).

As a result, in the voltage step-down circuit 20 according to the present embodiment, a variation of the output voltage (Va′, Vb′) caused by a leakage current can be further reduced as compared to the voltage step-down circuit 200 according to Comparative Example 2.

Further, by operating the switches IN1 to IN4 and the switches OUT1 to OUT4 according to the control waveforms of the switches illustrated in FIG. 6, the capacitive step-down circuit CDIV that steps down the voltage Va applied to the diode D1 and the capacitive step-down circuit CDIV that steps down the voltage Vb applied to the diode D2 can be periodically interchanged. In the example of FIG. 6, in the period T1 to T5, the set including the capacitive step-down circuits CDIV1 and CDIV2 steps down the voltage Va, and the set including the capacitive step-down circuits CDIV3 and CDIV4 steps down the voltage Vb. On the other hand, in the period T5 to T9, the set including the capacitive step-down circuits CDIV1 and CDIV2 steps down the voltage Vb, and the set including the capacitive step-down circuits CDIV3 and CDIV4 steps down the voltage Va.

Due to the above-described control of the switches IN1 to IN4 and the switches OUT1 to OUT4, a variation of the output voltages (Va′, Vb′) caused by a variation of a circuit element between the circuit element of the capacitive step-down circuits CDIV1 and CDIV2 and the circuit element of the capacitive step-down circuits CDIV3 and CDIV4 can be averaged.

As a result, in the voltage step-down circuit 20 according to the present embodiment, changes in the output voltage caused by a variation of a circuit element can be further reduced as compared to the voltage step-down circuit 200 according to Comparative Example 2. Accordingly, in the voltage step-down circuit 20 according to the present embodiment, a stepped-down voltage that is only slightly affected by a variation of a circuit element can be obtained.

### Second Embodiment

Next, a second embodiment will be described.

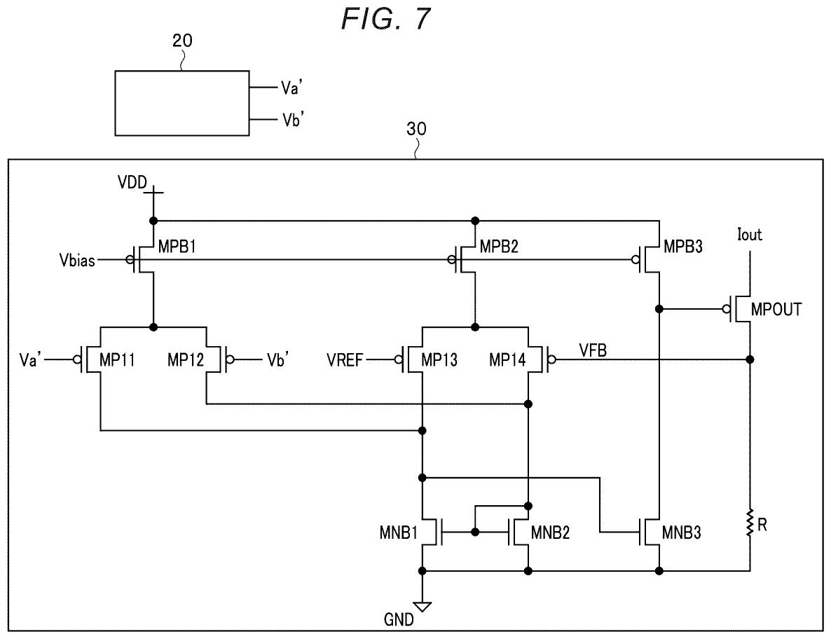

FIG. 7 is a circuit diagram illustrating a configuration of a current generator circuit. The voltages Va′ and Vb′ that are the output voltages of the voltage step-down circuit 20 are input to a current generator circuit 30 illustrated in FIG. 7.

The current generator circuit 30 includes PMOS transistors MPB1, MPB2, MPB3, MPOUT, MP11, MP12, MP13, and P14, NMOS transistors MNB1, MNB2, MNB3, and a resistor R.

A bias voltage Vbias is input to gates of the PMOS transistors MPB1, MPB2, and MPB3. The voltages Va′ and Vb′ that are the output voltages of the voltage step-down circuit 20 are input to gates of the PMOS transistors MP11 and MP12.

A reference voltage VREF is input to a gate of the PMOS transistor MP13. A gate of the PMOS transistor MPOUT is connected to a drain of the PMOS transistor MPB3. A feedback voltage VFB is input to a gate of the PMOS transistor MP14.

A drain of the PMOS transistor MPOUT is connected to the resistor R, and the feedback voltage VFB applied to the resistor R is represented by Expression (10).

$$VFB = VREF + {Va}^{′} - {Vb}^{′} \qquad ( 10 )$$

Here, when a step-down ratio of the capacitive step-down circuits CDIV1, CDIV2, CDIV3, and CDIV4 of FIG. 5 is represented by D_{SC}, the diode voltage difference Va′-Vb′ is represented by Expression (11) based on Expression (9) above.

$${Va}^{′} - {Vb}^{′} = {D}_{S C} \frac{kT}{q} ln ( MN ) \qquad ( 11 )$$

As a result, an output current Iout is represented by Expression (12) based on Expressions (10) and (11).

$$Iout = \frac{FB}{R} = \frac{1}{R} \{ VREF + {D}_{SC} \frac{k T}{q} ln ( N ) \} \qquad ( 12 )$$

As a result, in the current generator circuit 30 according to the present embodiment, an output current having temperature characteristics can be obtained. In the current generator circuit 30 according to the present embodiment, the effects of a leakage current and a variation of a circuit element on the step-down ratio D_{SC} can be further reduced as compared to the circuit configuration of FIG. 5, and thus the output current Iout for high-accuracy temperature characteristic correction can be obtained. By inputting this output current Iout to another circuit, a control of eliminating the temperature dependence of the other circuit to which the output current Iout is input can be implemented.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor integrated circuit comprising:
a plurality of step-down circuits configured to step down a first voltage that is input and to output a first stepped-down voltage or to step down a second voltage that is input and to output a second stepped-down voltage;
a plurality of input switches connected to input terminals of the plurality of step-down circuits, respectively, each of the input switches being configured to switch an input to the corresponding input terminal to either the first voltage or the second voltage; and
a plurality of output switches connected to output terminals of the plurality of step-down circuits, respectively, each of the output switches being configured to switch an output from the corresponding output terminal to either a first output node or a second output node.

2. The semiconductor integrated circuit according to claim 1, wherein
the plurality of step-down circuits include first, second, third, and fourth step-down circuits,
the plurality of input switches includes first, second, third, and fourth input switches,
the plurality of output switches includes first, second, third, and fourth output switches,
the first input switch, the second input switch, the first output switch, and the second output switch are operated in synchronization with each other, and
the third input switch, the fourth input switch, the third output switch, and the fourth output switch operate in synchronization with each other and complementary to the first input switch, the second input switch, the first output switch, and the second output switch.

3. The semiconductor integrated circuit according to claim 2, wherein
each of the first, second, third, and fourth step-down circuits includes a first switch configured to control charging of an input voltage that is input through the input terminal, a first capacitor charged with the input voltage, a second capacitor that is stepped down in voltage by being connected to the charged first capacitor in parallel, a second switch configured to connect the first capacitor and the second capacitor to each other and to control a step-down operation of the input voltage, a third switch configured to discharge charge in the second capacitor, and a fourth switch configured to cut-off the output terminal when the second capacitor is discharged or the step-down operation is executed.

4. The semiconductor integrated circuit according to claim 3, further comprising a signal generator circuit configured to generate and output control signals for controlling the plurality of input switches.

5. The semiconductor integrated circuit according to claim 4, wherein the control signals are signals that are time divided from a control signal to be supplied to the first switch provided in each of the plurality of step-down circuits.

6. The semiconductor integrated circuit according to claim 3, wherein
the first switch of the first step-down circuit and the first switch of the third step-down circuit are switched on/off in synchronization with each other, and
the first switch of the second step-down circuit and the first switch of the fourth step-down circuit are switched on/off in synchronization with each other.

7. The semiconductor integrated circuit according to claim 3, further comprising:
a first circuit connected to the first output node and the second output node and configured to generate an output current; and
a second circuit to which the output current is supplied.

8. The semiconductor integrated circuit according to claim 1, wherein
the first voltage is a voltage that is applied to a first diode having one end connected to a first constant current source, and
the second voltage is a voltage that is applied to a second diode that is connected in parallel to the first diode and has one end connected to a second constant current source.

9. A memory controller comprising:
a step-down circuit configured to step down a first voltage that is input and to output a first stepped-down voltage or to step down a second voltage that is input and to output a second stepped-down voltage;
an input switch connected to an input terminal of the step-down circuit, the input switch being configured to switch an input to the input terminal to either the first voltage or the second voltage;
an output switch connected to an output terminal of the step-down circuit, the output switch being configured to switch an output from the output terminal to either a first output node or a second output node;
a signal generator circuit configured to generate and output control signals for controlling the input switch and the output switch; and
a control circuit configured to control reading and writing of a semiconductor memory device using the voltage at the first output node and the second output node.

10. The memory controller according to claim 9, wherein
the step-down circuit includes a first switch configured to control charging of an input voltage that is input through the input terminal, a first capacitor charged with the input voltage, a second capacitor that is stepped down in voltage by being connected to the charged first capacitor in parallel, a second switch configured to connect the first capacitor and the second capacitor to each other and to control a step-down operation of the input voltage, a third switch configured to discharge charge in the second capacitor, and a fourth switch configured to cut-off the output terminal when the second capacitor is discharged or the step-down operation is executed, and
the signal generator circuit is further configured to generate and output control signals for controlling the first switch, the second switch, the third switch, and the fourth switch.

11. The memory controller according to claim 10, wherein the control signals for the input switch and the output switch are derived from the control signal for the first switch.

12. The memory controller according to claim 11, wherein
the first switch and the third switch are operated in synchronization with each other, and
the second switch and the fourth switch are off when the first switch and the third switch are on.

13. The memory controller according to claim 12, wherein the second switch is off when the third switch is on and the third switch is off when the second switch is on.

14. The memory controller according to claim 9, wherein
the first voltage is a voltage that is applied to a first diode having one end connected to a first constant current source, and
the second voltage is a voltage that is applied to a second diode that is connected in parallel to the first diode and has one end connected to a second constant current source.

15. The memory controller according to claim 9, further comprising:
a current generating circuit connected to the first output node and the second output node and configured to generate an output current that is supplied to the control circuit.

16. A control method of a semiconductor integrated circuit comprising:
a plurality of step-down circuits configured to step down a first voltage that is input and to output a first stepped-down voltage or to step down a second voltage that is input and to output a second stepped-down voltage;
a plurality of input switches connected to input terminals of the plurality of step-down circuits, respectively, each of the input switches being configured to switch an input to the corresponding input terminal to either the first voltage or the second voltage; and
a plurality of output switches connected to output terminals of the plurality of step-down circuits, respectively, each of the output switches being configured to switch an output from the corresponding output terminal to either a first output node or a second output node, wherein:
the plurality of step-down circuits include first, second, third, and fourth step-down circuits;
the plurality of input switches includes first, second, third, and fourth input switches;
the plurality of output switches includes first, second, third, and fourth output switches; and
the control method comprises:
operating the first input switch, the second input switch, the first output switch, and the second output switch in synchronization with each other, and
operating the third input switch, the fourth input switch, the third output switch, and the fourth output switch in synchronization with each other and complementary to the first input switch, the second input switch, the first output switch, and the second output switch.

17. The method according to claim 16, wherein
each of the first, second, third, and fourth step-down circuits includes a first switch configured to control charging of an input voltage that is input through the input terminal, a first capacitor charged with the input voltage, a second capacitor that is stepped down in voltage by being connected to the charged first capacitor in parallel, a second switch configured to connect the first capacitor and the second capacitor to each other and to control a step-down operation of the input voltage, a third switch configured to discharge charge in the second capacitor, and a fourth switch configured to cut-off the output terminal when the second capacitor is discharged or the step-down operation is executed.

18. The method according to claim 17, further comprising:
generating a control signal to be supplied to the first switch provided in each of the plurality of step-down circuits; and
generating control signals for controlling the plurality of input switches from the control signal to be supplied to the first switch.

19. The method according to claim 17, further comprising:
operating the first switch of the first step-down circuit and the first switch of the third step-down circuit in synchronization with each other; and
operating the first switch of the second step-down circuit and the first switch of the fourth step-down circuit in synchronization with each other.

20. The method according to claim 17, further comprising:
generating an output current based on voltages at the first output node and the second output node; and
supplying the output current to another circuit.
